(19) United States
(12) Patent Application Publication
(10) Pub. No.: US 2007/0205476 A1
(43) Pub. Date: Sep. 6, 2007

(54) Printed magnetic rom-mprom

(75) Inventor: Gavin Nicholas Phillips, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/598,640

(22) PCT Filed: Mar. 3, 2005
(86) PCT No.: PCT/IB05/50797

§ 371 Date: Sep. 7, 2006

(30) Foreign Application Priority Data
Mar. 12, 2004 (EP) 04101018.2

(51) Int. Cl. H01L 43/00; B05D 5/12; B05D 5/00

(52) U.S. Cl. 257/421; 427/127; 427/256

(57) ABSTRACT

The invention relates to a method for storing information on a storage device (100) by depositing electromagnetic material (104) in a pattern on a sensor surface (106) of the storage device, the pattern representing the information to be stored. The storage device (100) comprises an array of sensor elements (101) that are sensitive to electromagnetic material (104) within a near field working distance (105). The read-out is done by a resistance measurement which relies on a magneto resistance phenomenon detected in a multilayer stack of the sensor elements (101). The storage device (100), comprising the deposited pattern of electromagnetic material (104), is a Read Only Memory device. The deposition of the pattern is, for example, possible by scanning a depositing unit (403), e.g. a printer head, in a line-by-line motion across the sensor surface (106), resulting in a Printed Magnetic ROM.

The invention relates to a method for storing information on a storage device.

The invention further relates to a storage device.

The invention also relates to a method for manufacturing a storage device.

For storage of digital data several types of solid state devices are known, such as semiconductor memory circuits of the RAM, ROM or EPROM type. A promising new type of storage device is the so-called MRAM, a magnetic random access memory, based on a magnetic material and electronic circuitry to set and detect the magnetic state of bit locations of the material.

A magnetic random access memory (MRAM) is known from the article: “A 256 kb 3.0V 1T1MTJ Nonvolatile Magneto resistive RAM by Peter K. Naji et al, as published for the 2001 IEEE International Solid-State Circuits Conference 0-7803-76608-5, ISSCC2001/Session 7/Technology directions: Advanced Technologies/7.6”. The MRAM device has a free magnetic layer for information storage. In the device an array of bit cells is accommodated, the bits cells having an electronic sensor element and a bit location on the free magnetic layer. The magnetic state of the material of the free magnetic layer represents a logical value of the bit location. In a read mode the sensor element is arranged for detecting the magnetic state, in particular via a tunneling magneto-resistive effect (TMR). Current is guided via a tunneling barrier wherein the tunnel probability is influenced by the magnetic state, resulting in a change of the resistance of the sensor element. In a program (or write) mode a strong program current is guided via a programming circuit and causes a magnetic field strong enough to set the magnetic state at the respective bit location in dependence on the program current. It is to be noted that such a MRAM is of a non-volatile type, i.e. the logical values of the bit locations do not change if the device is with or without operating power. Hence the MRAM device is suitable for devices that need to be active shortly after power-on. A problem of the known device is that the stored value of the bit locations has to be programmed by applying the program current for each individual bit cell, which requires a relatively complex circuitry at each bit cell plus addressing electronics.

Therefore it is an object of the invention to provide the stored values of the bit locations in an efficient way.

According to a first aspect of the invention the object is achieved with a method for storing information in a storage device, the storage device comprising a two-dimensional array of electromagnetic sensor elements that are sensitive at a sensor surface to electromagnetic material within a near field working distance, the method for storing information comprises a step of depositing the electromagnetic material in a pattern on the sensor surface, the pattern representing the information.

According to a second aspect of the invention the object is achieved with a storage device, which comprises a two-dimensional array of electromagnetic sensor elements that are sensitive at a sensor surface to electromagnetic material within a near field working distance, wherein the sensor surface is arranged for depositing the electromagnetic material. The storage device according to the invention is particularly meant for use in the method for storing information as claimed in claim 1.

According to a third aspect of the invention the object is achieved with a method for manufacturing a storage device as claimed in claim 8, comprising a step of manufacturing a two-dimensional array of electromagnetic sensor elements that are sensitive at a sensing surface to electromagnetic material within a near field working distance, and further comprising a step of preparing the sensor surface for depositing electromagnetic material.

The effect of the measures is that the stored values are provided to the bit locations of the sensor elements by depositing electromagnetic material on a sensor surface of the storage device in a pattern representing the information. The storage device comprises a two-dimensional array of sensor elements. The sensor elements are able to sense the presence of electromagnetic material at the sensor surface, within a certain distance from the sensor elements, the so called near field working distance. The information which is to be stored on the storage device is coded into the two-dimensional pattern. Depositing the electro-magnetic material in the two-dimensional pattern on the sensor surface of the storage device is an efficient way of providing the array of sensor elements with the stored values of the information.

The sensor elements are different in that they detect the presence of deposited material within the near field working distance, while MRAM cells detect a magnetic state. One way of detecting the presence of the material is through generating a magnetic or electric field by the sensor elements and sensing a disturbance of the field caused by the material. The field is generated through field generating means within the sensor element. The sensed disturbance depends on the type of electro-magnetic material, on the distance between the sensor element and the material and on the amount of electromagnetic material, which is present within the near field working distance. Another way of detecting the presence of the material is by depositing the pattern using hard magnetic material. The hard magnetic material deposited at a sensor generates a static magnetic field, which is sensed by the sensor element.

Another difference between the sensor elements and MRAM cells is that the storage device cannot influence the information content because it cannot change the pattern of the electromagnetic material which is deposited on the sensor surface. Therefore, the device is a Read-Only-Memory device.

In addition, the device has cost benefits compared to the MRAM devices, because the sensor elements are less complex than the usual bit cell elements in an MRAM device. The main difference is that no writing circuitry is needed to store data in the storage device. When hard magnetic material is used for depositing the pattern, even the field generating electronics can be omitted.

Finally, the system provides protection against copying the content, because the user may not have access to a similar storage device of a writable type.

The inventors have used a material that is called electromagnetic in this document because its presence or absence is detectable via an electrical and/or magnetic field. In an embodiment, the electrical and/or magnetic field (also called bias field) is generated by a sensor element. It is noted that the sensing of the value of a bit location in this case does not depend on the magnetic state of the material, but on the presence or absence of the material itself, on the type of electromagnetic material used, or on the amount of electro-magnetic material which is present within the near field working distance of the sensor elements. In this embodiment, the electromagnetic sensor element can generate the bias field and can detect disturbances in the field extending over a predefined near field working distance, which is in practice in the same order of magnitude as the minimum dimensions of the bit location. In another embodiment, a magnetic field is generated by the hard magnetic material which is deposited in the pattern on the sensor surface of the storage device. The sensor elements are able to detect the static magnetic fields from the hard magnetic material without generating an electrical or magnetic field.

The sensor surface of the storage device is arranged for depositing the electro-magnetic material by, for example, leveling and/or processing the sensor surface to enable deposition of the material. The processing step may, for example, comprise roughening the surface to achieve a strong adhesion of the electromagnetic material onto the surface. It may also comprise, for example, applying alignment structures through which the pattern can be positioned on the sensor surface of the storage device. The processing of the sensor surface is done during the preparation step in the method of manufacturing.

In an embodiment of the method for storing information, the method comprises a step of aligning the pattern of electromagnetic material to correspond to the array of electro-magnetic sensor elements. In contrast to an embodiment shown below, where a non-aligned image is deposited on the sensor surface, this embodiment ensures a clear definition between the deposited pattern and the sensor elements. There are several possible ways through which the pattern is aligned to the sensor elements. The pattern is, for example, aligned to the sensor elements by using alignment structures on the sensor surface. Alternatively, for example, mechanical cams are used for positioning a deposition apparatus with respect to the sensor elements. Another example is by active alignment, in which the value sensed by the sensor elements is used to align the pattern, for example, by sensing the signal strength during deposition of the electromagnetic material, allowing corrections in the positioning of the pattern with respect to the sensor elements.

In an embodiment of the method for storing information, the method comprises a printing step for depositing the electromagnetic material. In this embodiment the pattern is created by scanning with a printer head over the sensor surface, depositing the electromagnetic material on the sensor surface in the required pattern. The electro-magnetic material is deposited during a scanning motion of the printer head or the sensor. This embodiment shows a simple and relatively cheap method for creating the pattern on the sensor surface after the storage device has been manufactured. This method for storing information is especially beneficial for single copies or when a limited amount of data needs to be stored.

In an embodiment of the method for storing information, the method comprises a stamping step for depositing the electromagnetic material, in particular using a finger. For this embodiment, a stamp is created, being a two-dimensional representation of the pattern. The stamp is used to deposit electromagnetic material on the sensor surface. Alternatively objects may be used as a stamp to deposit the electromagnetic material, for example, a finger to deposit electromagnetic material in the shape of a fingerprint on the sensor surface. Also this method enables the creation of the pattern on the sensor surface in a simple and relatively cheap manner. This embodiment is especially beneficial for creating a medium number of copies due to the ease of reproduction.

In an embodiment of the method for storing information, the storage device has a cover layer providing the sensor surface, wherein the step of depositing electro-magnetic material in a pattern comprises: depositing a layer of electromagnetic material on the sensor surface, and comprises creating a pattern of depressed portions into the cover layer whereby the sensor surface in the depressed portions is within the near field working distance and the sensor surface outside the depressed portions is outside the near field working distance. In this embodiment, the information is applied to the storage device by deforming the cover layer in a pattern of depressed portions, which represent the information to be stored. The deformations bring the depressed portions within the near field working distance of the sensor elements of the storage device. The non-deformed part of the cover layer remains outside the near field working distance. In a first embodiment, the electromagnetic material is deposited on the sensor surface in a continuous layer after the depressed portions have been applied to the cover layer. At the depressed portions the electromagnetic material of the continuous layer is located within the near field working distance of the sensor elements, influencing the value sensed by the sensor elements. Alternatively, in a second embodiment, the continuous layer of electromagnetic material is deposited to the sensor surface before the pattern is applied. Deforming the cover layer in a pattern of depressed portions brings the electromagnetic material within the near field working distance of the sensor elements, which is sensed by the sensor elements. The benefit of these embodiments is that a pure mechanical deformation of the sensor surface enables the creation of the pattern, which is mainly beneficial for creating a high number of copies.

In an embodiment of the method for storing information, the storage device has a cover layer providing the sensor surface, wherein the method for storing information comprises a step of embedding the electromagnetic material into the cover layer. Embedding the electromagnetic material into the cover surface of the storing device may be done in several ways. One example of embedding the pattern of electromagnetic material is by heating (possibly locally) the cover layer after the material has been deposited on the sensor surface. The pattern of electromagnetic material will sink or diffuse into the cover layer resulting in the embedding of the material. Alternatively, for example, implanting methods used in semiconductor manufacturing may be applied for embedding electromagnetic material into the cover layer. One benefit of embedding the electromagnetic material into the cover layer is that the pattern is protected from damage and environmental influences. Another benefit is that the pattern cannot easily be altered or copied.

In an embodiment of the method for storing information, the step of depositing electromagnetic material in a pattern comprises depositing a pattern comprising at least two types of electromagnetic material, the types of electro-magnetic material representing different values to the sensor elements. The type of electromagnetic material can be different by using different material or by using different concentrations of the same material. Because the types of electromagnetic material represent different values to the sensor elements, the storage device can discriminate between the different types of material. This results in two possible embodiments. A first embodiment comprises a single pattern comprising at least two types of electromagnetic material. Each bit location on the storage device comprises a discrete value rather than a binary state. The discrete value is depending on the type of material located at the bit location. A second embodiment comprises depositing more than one pattern of information, each pattern deposited with a different type of electromagnetic material. Both embodiments enhance the storage capacity of the storage device.

In an embodiment of the storage device, the sensor elements are arranged for sensing a value in a range of values depending on an amount of electromagnetic material within the near field working distance. In this embodiment of the storage device, the value sensed by the sensing element is within a range of values, rather than a digital value. The range of values may be a continuous range or a range of discrete values. The actual value sensed by the sensor elements depends on the amount of electromagnetic material which is located within the near field working distance of the sensor. This embodiment enables, for example, storing and digitization of an image deposited on the sensor surface with electro-magnetic material.

It is noted that a not yet pre-published patent application “Read-only memory device MROM” (Filing No.: IB03/04009) describes a magnetic ROM device comprising a read-out part with a physically separate information part. After the information has been applied to the information part, the storage device is assembled by aligning the information part to the read-out part and fixedly coupling the two parts. The current invention is different in that the pattern of electromagnetic material, which represents the information, is deposited directly on the sensor surface of the storage device.

These and other aspects of the invention will be apparent from and elucidated further with reference to the embodiments described by way of example in the following description and with reference to the accompanying drawings, in which

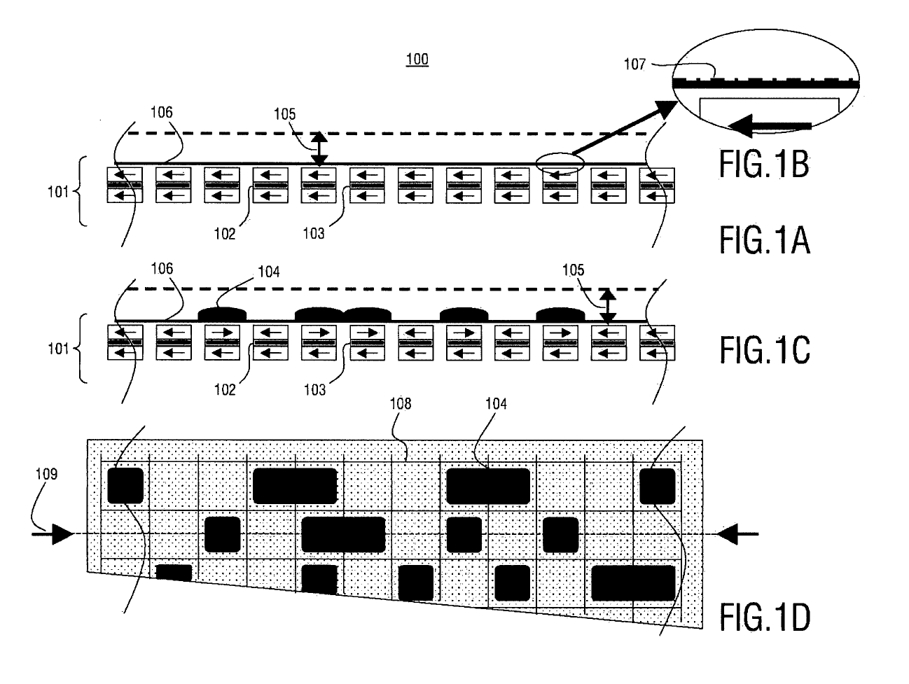

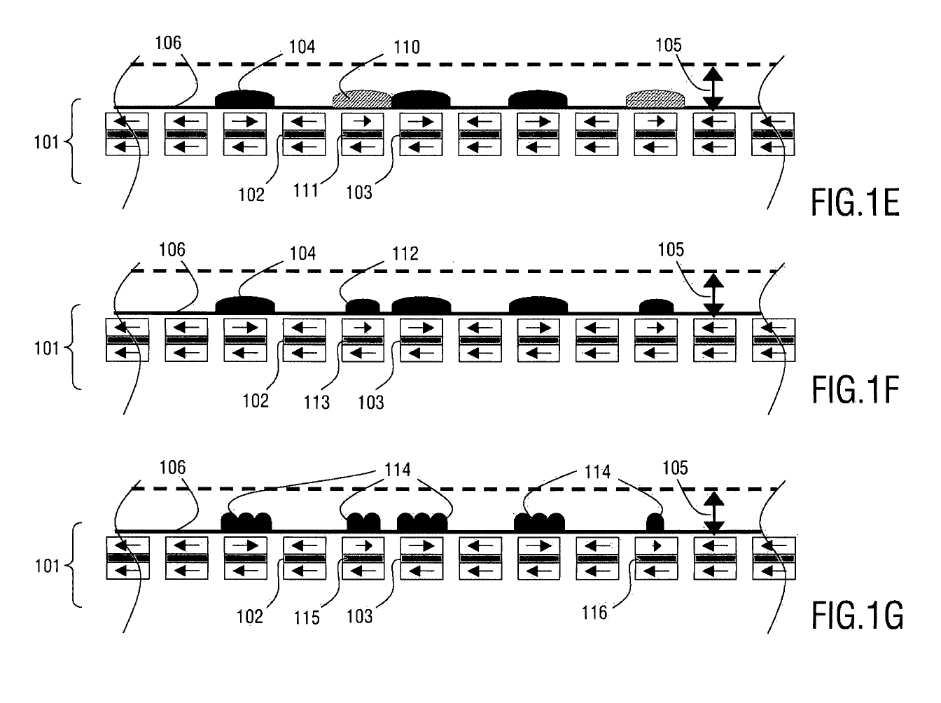

FIG. 1A shows a cross-sectional view of a storage device according to the invention,

FIG. 1B shows a detailed view of the sensor surface arranged for depositing electromagnetic material,

FIG. 1C shows a cross-sectional view of a storage device according to the invention, on which a pattern of electromagnetic material, representing the information, has been deposited,

FIG. 1D shows a top-view of a storage device according to the invention, on which a pattern of electromagnetic material, representing the information, has been deposited,

FIG. 1E shows a cross-sectional view of a storage device according to the invention, on which a pattern of electromagnetic material, representing the information, has been deposited by using two types of electro-magnetic material,

FIG. 1F shows a cross-sectional view of a storage device according to the invention, on which a pattern of electromagnetic material, representing the information, has been deposited by using different amounts of electromagnetic material,

FIG. 1G shows a cross-sectional view of the storage device according to the invention, on which a pattern of electromagnetic material, representing the information, has been deposited by using small units of electromagnetic material and adapting the number of units per sensor to influence the value sensed by the sensor,

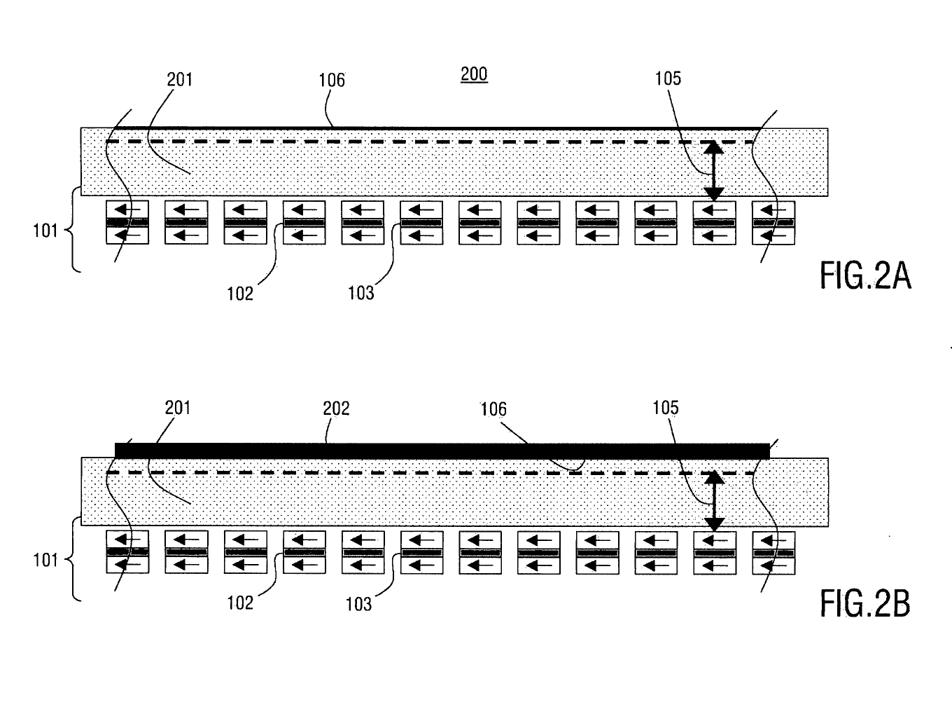

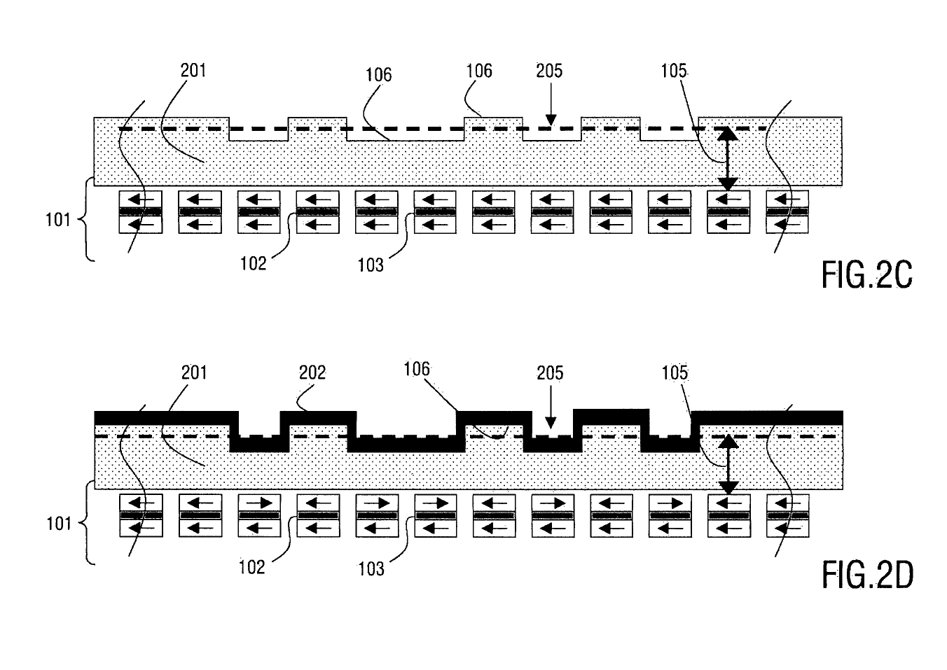

FIG. 2A shows a cross-sectional view of a storage device according to the invention, in which a cover layer providing the sensor surface has been applied on the storage device,

FIG. 2B shows a cross-sectional view of the storage device where a layer of electromagnetic material is deposited on the sensor surface of the cover layer,

FIG. 2C shows a cross-sectional view of the storage device where a pattern of depressed portions, representing the information, is created in the cover layer,

FIG. 2D shows a cross-sectional view of the storage device where the electro-magnetic material in the depressed portions is within the near field working distance of the sensing elements,

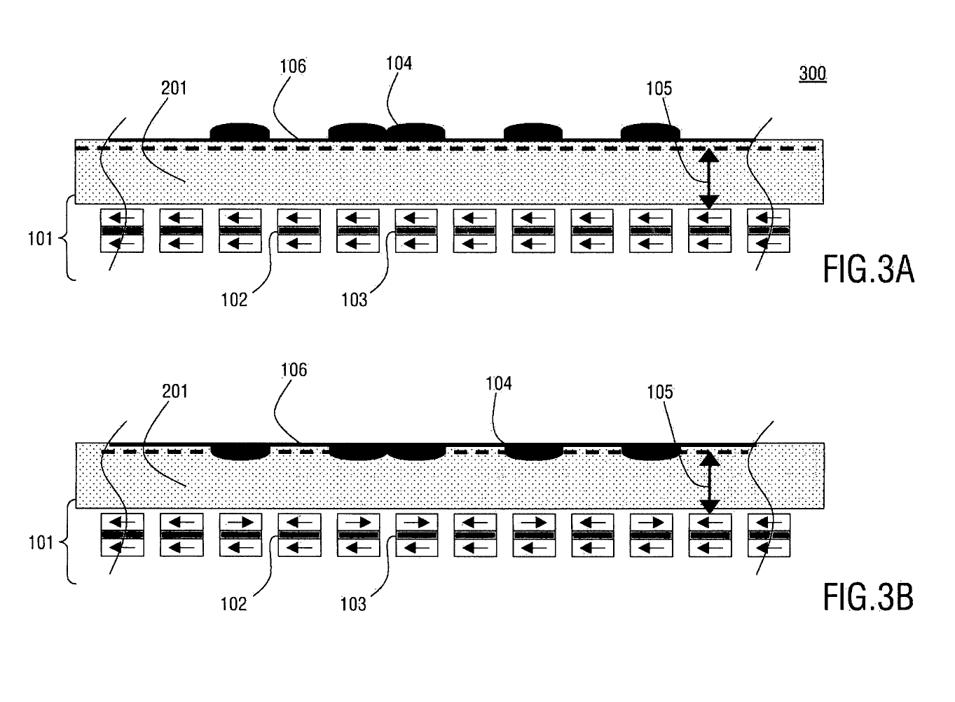

FIG. 3A shows a cross-sectional view of a storage device according to the invention, in which a cover layer providing the sensor surface has been applied to the storage device, and where a two-dimensional pattern of electromagnetic material, representing the information, has been deposited on the sensor surface,

FIG. 3B shows a cross-sectional view of a storage device in which the pattern of electromagnetic material, representing the information, is embedded inside a cover-layer,

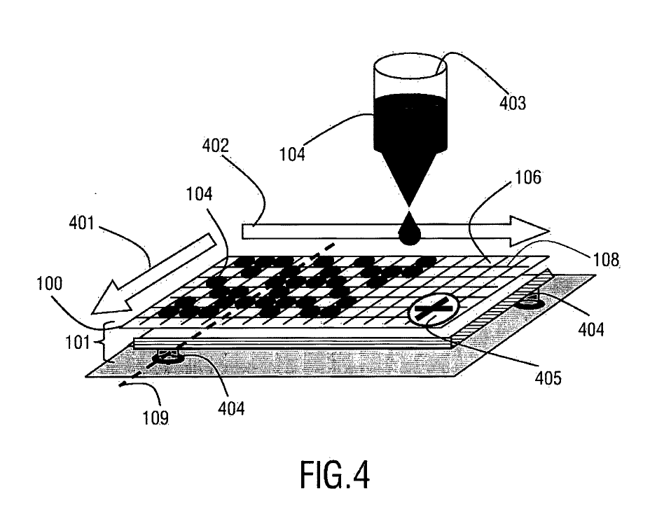

FIG. 4 shows an apparatus for depositing the electromagnetic material in a pattern, representing the information, on the storage device,

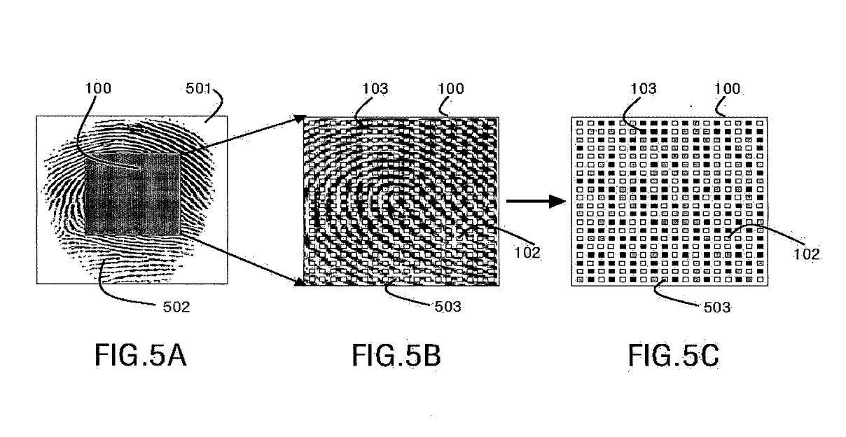

FIG. 5A shows a top-view of a storage device on which an image is deposited with electromagnetic material,

FIG. 5B shows a top-view of the storage device of FIG. 5A in detail where the position of the sensor elements with respect to the electromagnetic material is shown,

FIG. 5C shows a top-view of the storage device as shown in FIG. 5B where the different values as sensed by the sensor elements are shown by using different grey-scales,

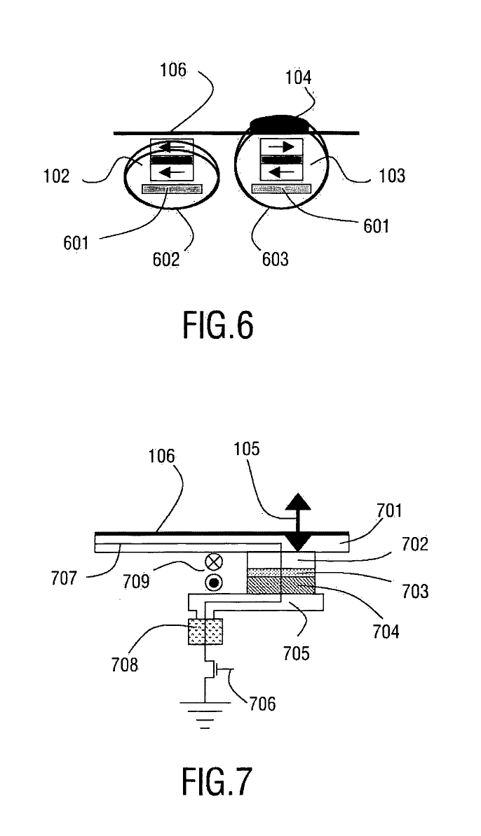

FIG. 6 shows sensor elements within a near field working distance of a sensor surface, and

FIG. 7 shows a sensor element in detail.

In the Figures, elements which correspond to elements already described have the same reference numerals.

FIG. 1A shows a cross-sectional view of a storage device 100 according to the invention. The storage device 100 comprises an array of sensor elements 101 and a sensor surface 106. The array of sensor elements 101 comprises electromagnetic sensor elements 102, 103, which can detect the presence or absence of electromagnetic material 104 (FIG. 1C) within the near field working distance 105. In one embodiment, the detection of the electro-magnetic material 104 is based on the disturbance of an electrical or magnetic field generated by the sensor elements 102, 103 by the presence of said electromagnetic material 104. This is explained in more detail in FIG. 6. In another embodiment, the electromagnetic material 104 is a hard magnetic material. In this embodiment, the sensor elements 102, 103 can sense the presence of the material 104 by sensing the static magnetic field of the hard magnetic material. The sensing of the material is in this case done without generating an electrical or magnetic field. In this embodiment, the field generating lead (601, see FIG. 6) of the sensor elements 102, 103 may be omitted. The sensor surface 106 of the storage device 100 is arranged for depositing the electro-magnetic material 104, as is shown in FIG. 1B.

FIG. 1B shows a detailed view of a roughened sensor surface 107 arranged for depositing electromagnetic material 104. In this embodiment, the sensor surface 107 is roughened to achieve a strong adhesion of the electromagnetic material 104 onto the surface 107. Other possible arrangements for depositing electro-magnetic material 104 are, for example, applying small dents at the location of the sensor elements 102, 103 indicating the position of the sensor elements 102, 103 at the sensor surface 106 (not shown) or, for example (see FIG. 4), applying alignment structures 405 on the sensor surface 106 to enable the alignment of a depositing apparatus with respect to the sensor elements 102, 103.

FIG. 1C shows a cross-sectional view of a storage device 100 according to the invention, on which a pattern of electromagnetic material 104, representing the information, has been deposited. In the current embodiment, the electromagnetic material 104 is directly deposited on the sensor surface 106 of the storage device 100. The information is represented by a two-dimensional pattern (see also FIG. 1D) corresponding to the sensor elements 102, 103. Each sensor element 102, 103 detects a single logical value at the corresponding surface area of the sensor surface 106. The presence or absence of electromagnetic material 104 within the near field working distance 105 determines the state of the bit location (“1” or “0”). The two-dimensional pattern is aligned with respect to the sensor element 102, 103. For this alignment several alignment methods are possible. For example (see FIG. 4), cams 404 may be used to mechanically align the storage device 100 inside a deposition apparatus. In another example, optical alignment structures 405 may be used to align a deposition apparatus with respect to the sensor elements 102, 103, before depositing the pattern of electromagnetic material 104 onto the sensor surface 106. The two-dimensional pattern may also be aligned using active alignment, where the signal strength of the sensor elements is used to align the pattern. For example, by measuring the sensed value of the sensor elements 102, 103 while depositing the electromagnetic material 104 and allowing corrections in the positioning of the pattern while depositing. Alternatively, an alignment part (not shown), being a small part of the sensor array 101, may be assigned specially for performing this active alignment, for example, by depositing a pattern at the alignment part of the sensor surface 106 and measuring the signal of the sensor element 102, 103 during and/or after deposition, from which alignment information can be retrieved. The pattern of electro-magnetic material 104 is directly deposited on the sensor surface 106, for example, through micro-contact printing, liquid embossing, screen-printing, stamping, wave printing, ink-jet printing (see also FIG. 4), etc. The choice of the used method mainly depends on the required bit resolution on the sensor surface 106.

FIG. 1D shows a top-view of a storage device 100 according to the invention, on which a pattern of electromagnetic material 104, representing the information, has been deposited. The dashed line 109 represents the cross-section which is shown in FIG. 1B. The gridlines 108 circumscribe the two-dimensional array of bit locations. At each of these bit locations a sensor element 102, 103 is present in the sensing layer 101.

FIG. 1E shows a cross-sectional view of a storage device 100 according to the invention, on which a pattern of electromagnetic material 104, 110, representing the information, has been deposited by using two types of electromagnetic material 104, 110. The two materials 104, 110 may be different because of the type of material or because of different concentration of the same material. The sensor elements 103, 111, sense a different value depending on the type of material 104, 110 located within the near field working distance 105. Because different electromagnetic materials 104, 110 can be used on the storage device 100, the stored information comprises discrete values rather than binary values. The resulting storage device 100 may either comprise two different patterns of information, both deposited with a different electromagnetic material 104, 110, or may comprise one pattern of information deposited with two different electro-magnetic materials 104, 110. Depending on the sensitivity of the sensor elements 102, 103, 111, more than two electromagnetic materials may be used. The advantage of these embodiments is that the storage capacity of the storage device is enhanced.

FIG. 1F shows a cross-sectional view of a storage device 100 according to the invention, on which a pattern of electromagnetic material 104, 112, representing the information, has been deposited by using different amounts of electromagnetic material 104, 112. The value sensed by the sensor elements 103, 113 depends on the amount of electro-magnetic material 104, 112 located within the near field working distance 105. By changing the amount of electromagnetic material in discrete steps, a range of discrete values is created, comparable to the use of different materials, shown in FIG. 1E. Allowing a continuous variation in the amount of electro-magnetic material creates a continuous range of possible values. The range of possible values (both the continuous and the discrete range) depends on the sensitivity of the sensor elements 102, 103, 113, and the sensing electronics. This embodiment is especially beneficial when the deposited pattern is an image which is not aligned to the sensor elements 102, 103, 113. By allowing a continuous range of possible sensed values, the storage device 100 can, next to storing the deposited image, digitize the image (e.g. 502 at FIG. 5A) and convert the information into grey-tones, depending on the amount of electromagnetic material 104, 112 located within the near field working distance 105 of each sensor 102, 103, 113. In the embodiment shown in FIGS. 5A, 5B and 5C and image 502 is deposited, stored and digitized. This image is deposited on the sensor surface 106 by using a fingerprint comprising electromagnetic material 104, 112, as a stamp.

FIG. 1G shows a cross-sectional view of the storage device 100 according to the invention, on which a pattern of electromagnetic material, representing the information, has been deposited by using small units of electromagnetic material 114 and adapting the number of units per sensor element 102, 105, 115, 116 to influence the value sensed by the sensor element 102, 105, 115, 116. The value sensed by the sensor elements 102, 105, 115, 116 is depending on the amount of electromagnetic material 114 within the near field working distance 105 (as is explained at FIG. 1F). The range of values that can be sensed with this embodiment is depending on the sensitivity of the sensor elements 102, 105, 115, 116, on the sensing electronics and on the resolution with which the units of electro-magnetic material 114 can be deposited.

FIG. 2A shows a cross-sectional view of a storage device 200 according to the invention, in which a cover layer 201 providing the sensor surface 106 has been applied to the storage device 200. The sensor surface 106, which is on top of the cover layer 201, lies outside the near field working distance 105 of the sensor elements 102, 103. Starting from the storage device 200 as shown in FIG. 2A there are several methods for depositing electro-magnetic material in a pattern within the near field working distance 105 of the sensor elements 102, 103. The resulting embodiments are shown in FIG. 2D and FIG. 3B. FIG. 2B and 2C show possible intermediate steps through which the embodiment shown in FIG. 2D can be reached.

FIG. 2B shows a cross-sectional view of the storage device 200 where a layer of electromagnetic material 202 is deposited on the sensor surface 106 of the cover layer 201. The layer of electromagnetic material 202 is outside the near field working distance 105 of the sensor elements 102, 103. The pattern, representing the information, is created by deforming the cover layer 201, generating depressed portions 205 (FIG. 2D) at the appropriate bit locations. The deformations can, for example, be done by using a stamp which comprises the two-dimensional pattern and creates the depressed portions 205 at the appropriate sensor elements 103. The resulting depressed portions 205 bring the pattern of electromagnetic material of the layer 202 within the near field working distance 105 of the sensor elements 102, 103, resulting in the embodiment shown in FIG. 2D. This method is especially beneficial when a large volume of copies is required.

FIG. 2C shows a cross-sectional view of the storage device 200 where a pattern of depressed portions 205, representing the information, is created in the cover layer 201. The sensor surface 106 at the depressed portions 205 is within the near field working distance 105 of the sensor elements 102, 103, and the sensor surface 106 outside the depressed portions is outside the near field working distance of the sensor elements 102, 103. The depressed portions 205 can, for example, be created through deforming the cover layer 201 (as is explained at FIG. 2B), but also, for example, by etching the depressed portions into the cover layer 201 or, for example, by burning the depressed portions into the cover layer 201 using a focused laser beam (not shown). After the pattern of depressed portions 205 has been created in the cover layer 201, a layer of electromagnetic material 202 (not shown in FIG. 2C) is deposited on the sensor surface 106 of the cover layer 201. This brings electromagnetic material 202 within the near field working distance 105 of the sensor elements 102, 103, resulting in the embodiment shown in FIG. 2D.

FIG. 2D shows a cross-sectional view of the storage device 200 where the electromagnetic material 202 in the depressed portions 205 is within the near field working distance 105 of the sensing elements 102, 103. As described above, this embodiment is achieved from the embodiment shown in FIG. 2A either through intermediate steps shown in FIG. 2B or FIG. 2C. The two-dimensional pattern of depressed portions 205, which represents the information, bring electromagnetic material 202 in the pattern within the near field working distance of the sensor elements 102, 103.

FIG. 3A shows a cross-sectional view of a storage device 300 according to the invention, in which a cover layer 201 providing the sensor surface 106 has been applied to the storage device 300, and where a two-dimensional pattern of electro-magnetic material 104, representing the information, has been deposited on the sensor surface 106. The sensor surface 106, which is on top of the cover layer 201, may lie outside the near field working distance 105 of the sensor elements 102, 103. The pattern of electromagnetic material 104 is deposited on the sensor surface 106 as described at FIG. 1C. Because the sensor surface 106 lies outside the near field working distance 105, the sensor elements 102, 103, are not influenced by the pattern. Embedding the pattern of electro-magnetic material 104 in the cover layer 201 (as is shown in FIG. 3B) will bring the electromagnetic material inside the near field working distance 105 of the sensor elements 102, 103. To achieve this, several methods are possible. For example, by heating the cover layer 201, possibly locally, so that the electromagnetic material 104 sinks into the cover layer 201 or diffuses into the cover layer 201. The resulting embodiment is shown in FIG. 3B.

FIG. 3B shows a cross-sectional view of a storage device 300 in which the pattern of electromagnetic material 104, representing the information, is embedded inside a cover-layer 201. The embedding of electromagnetic material 104 can be achieved, next to the examples described at FIG. 3A, by, for example, applying a cover layer 201 on top of the embodiment shown in FIG. 1C. This embodiment, together with the embodiments described in FIG. 3A, embed a deposited pattern inside the cover layer. Alternatively, for example, by using material implanting methods used in semiconductor manufacturing processes (not shown), the pattern of electromagnetic material is implanted directly into the cover layer 201. The benefits of embedding the electromagnetic material 104 into the cover layer 201 are that the pattern is protected from damage and environmental influences and that the pattern cannot easily be altered or copied.

FIG. 4 shows an apparatus for depositing the electromagnetic material 104 in a pattern, representing the information, on the storage device 100. The depositing unit 403, for example, a printer head, scans the sensor surface 106 of the storage device 100 in a line-by-line motion, depositing electromagnetic material 104 on the sensor surface 106. The deposited two-dimensional pattern represents the information which is stored on the storage device 100. The gridlines 108 circumscribe the two-dimensional array of sensor elements 101, which are aligned to the coordinate axes 401, 402 of the depositing apparatus, for example, by using mechanical alignment cams 404 and/or by using optical alignment structures 405. The dashed line 109 represents the cross-section which is shown in FIG. 1B. Alternatively the depositing unit 403, for example, comprises different types of electro-magnetic material (resulting in a storage device shown in FIG. 1E) or, for example, deposits different amounts of electromagnetic material 104, depending on the required value at a specific sensor element (resulting in a storage device shown in FIG. 1F or FIG. 1G).

FIG. 5A shows a top-view of a storage device 100 on which an image 502 is deposited with electromagnetic material. The image of electromagnetic material 502 is deposited on an image surface 501 by using an object as a stamp. In this case a finger, comprising electromagnetic material, was used to deposit and store a fingerprint. The part of the image 502 which is located within the near field working distance 105 of the sensor elements 102, 103 of the storage device (indicated with the grey square in FIG. 5A) is stored and digitized by the storage device 100.

FIG. 5B shows a detailed view of the storage device of FIG. 5A, where the position of the sensor elements with respect to the electromagnetic material from the image 502 are shown. The amount of electromagnetic material 502 located within the near field working distance 105 of the sensor elements 102, 103, 503 determine the value sensed by the individual sensor elements 102, 103, 503. As indicated in previous embodiments, the range of possible values may be a discrete range or a continuous range of values depending, for example, on the sensitivity of the sensor elements 102, 103, 503 and on the electronics of the storage device 100.

FIG. 5C shows a top-view of the storage device as shown in FIG. 5B where the different values as sensed by the sensor elements 102, 103, 503 are shown by using different grey-scales. The sensor element 103 in FIG. 5B comprises the maximum amount of electro-magnetic material from the image 502 within the near field working distance 105, which is represented by a black square. The sensor element 102 comprises no electromagnetic material from the image 502 within the near field working distance 105, which is represented by a white square. The sensor element 503 comprises an intermediate amount of electro-magnetic material from the image 502 within the near field working distance 105, which is represented by a grey square.

FIG. 6 shows sensor elements within a near field working distance of a sensor surface. Two sensor elements 102, 103 of the array are shown. Above the sensor elements 102, 103 an sensor surface 106 is shown having electromagnetic material 104 close to the sensor element 103 and within its near field working distance 105. At the adjacent bit location close to the sensor element 102 no electromagnetic material is present within the near field working distance. The sensor elements 102, 103 are arranged for generating magnetic fields 602, 603, for example, as shown by guiding an electric current via a lead 601 beneath the sensor elements 102, 103. The magnetic field is influenced by the absence or presence of the electromagnetic material 104 as shown in the resulting magnetic fields 602, 603, which result in a different magnetic direction in a top layer of the sensor element 103. The direction is detected in sensor elements having a multilayer or single layer stack by using a magneto-resistive effect, for example GMR, AMR or TMR. The TMR type sensor is preferred for resistance matching reasons for the read-only sensor element of this invention.

As shown in the Figure the vicinity of a portion of the electromagnetic material on the sensor surface forces the field lines of a bias field away from the TMR-element. The material acts as a flux guide: the field lines go through the material instead of through the free layer of the spin-tunnel junction. If the stack of the spin-tunnel junction is designed such that the interlayer magnetostatic coupling results in an antiparallel magnetization configuration if no external magnetic field is applied, the vicinity of a protrusion of the magnetic layer results in a high resistance, while otherwise the bias field will cause a low resistance state. In an embodiment a current carrying conductor is used as field generating strap for the bias field. Alternatively this may be a permanent magnet. Many variants are possible for the bias fields and also stray fields may be used, as will be clear for the person skilled in the art. The bias field in the media can be in the plane of the substrate (as shown in the Figure), but one could alternatively also consider bias fields perpendicular to the substrate resulting in stray fields from the magnetic layer that have components in the plane of the layers of the spin-tunnel junctions. While the given examples use magnetoresistive elements with in-plane sensitivity it is also possible to use elements that are sensitive to perpendicular fields. For a further description of sensors using magnetoresistive effects refer to “Magnetoresistive sensors and memory” by K.-M.H Lenssen, as published in “Frontiers of Multifunctional Nanosystems”, page 431-452, ISBN 1-4020-0560-1 (HB) or 1-4020-0561-X (PB).

In the storage system data are represented by magnetization directions occurring at a sensor element due to the bit location opposite the sensor on the sensor surface. The read-out is done by a resistance measurement which relies on a magneto resistance (MR) phenomenon detected in a multilayer stack. Sensors can be based on the anisotropic magneto resistance (AMR) effect in thin films. Since the amplitude of the AMR effect in thin films is typically less than 3%, the use of AMR requires sensitive electronics. The larger giant magneto resistance effect (GMR) has a larger MR effect (5 to 15%), and therefore a higher output signal. The magnetic tunnel junctions use a large tunnel magneto resistance (TMR) effect, and resistance changes up to ≈50% have been shown. Because of the strong dependence of the TMR effect on the bias voltage, the useable resistance change in practical applications is at present around 35%. In general, both GMR and TMR result in a low resistance if the magnetization directions in the multilayer stack are parallel and in a high resistance when the magnetizations are oriented antiparallel. In TMR multilayers the sense current has to be applied perpendicular to the layer planes (CPP) because the electrons have to tunnel through the barrier layer; in GMR devices the sense current usually flows in the plane of the layers (CIP), although a CPP configuration might provide a larger MR effect, but the resistance perpendicular to the planes of these all-metallic multilayers is very small. Nevertheless, using further miniaturization, sensors based on CPP and GMR are possible.

FIG. 7 shows a sensor element in detail. The sensor has a bit line 701 of an electrically conductive material for guiding a read current 707 to a multilayer stack of layers of a free magnetic layer 702, a tunneling barrier 703, and a fixed magnetic layer 704. The stack is built on a further conductor 705 connected via a selection line 708 to a selection transistor 706. The selection transistor 706 couples said read current 707 to ground level for reading the respective bit cell when activated by a control voltage on its gate. The magnetization directions 709 present in the fixed magnetic layer 704 (also called pinned layer) and the free magnetic layer 702 determine the resistance in the tunneling barrier 703, similar to the bit cell elements in an MRAM memory. The magnetization in the free magnetic layer is determined by the material at the bit location opposite the sensor as described above with FIG. 6, when such material is within the near field working distance indicated by arrow 105.

In an embodiment no additional means are needed to generate the bias field, but the bias field is effectively built-in in the spin-tunnel junction. This might, for example, be accomplished in the following ways. A built-in permanent magnet is achieved by an additional hard-magnetic layer underneath or above the spin-tunnel junction, or by an “over-dimensioned” pinned layer, e.g. an exchange-biased layer, or the hard-magnetic layer in the case of a “pseudo-spin valve” like MR-element. It is important that the resulting magnetostatic coupling dominates any direct exchange coupling between pinned and free layer, as is generally the case for a spin-tunnel junction. The effect of the magnetostatic coupling on the free layer should be reduced sharply when the soft-magnetic layer of the sensor surface is close to the element, i.e. within the near field working distance. This can be accomplished by making the distance sufficiently small and the thickness of this layer sufficiently large. In an embodiment the material on the sensor surface is permanently magnetized in a direction parallel to the magnetization direction of the free layer in the sensor element. Because of flux closure protrusions on the sensor surface will lead to a reversal of the magnetization of the free layer, provided the coupling to the sensor surface is stronger than the coupling with the other layers within the MR element.

For the sensor elements, because of the different requirements compared to those for MRAM, the composition and characteristics of the spin-tunnel junctions are adapted compared to those used for MRAM. While for MRAM two stable magnetization configurations (i.e. parallel and antiparallel) are essential for the storage, this does not have to be the case for the proposed sensor element. Here read sensitivity is crucial, while a bi-stable magnetization configuration is in general not relevant. Of course the direction of the reference magnetization, e.g. in the pinned or exchange-biased layer should be invariant. Hence for the free layer, which acts as detection layer, materials with a low coercivity can be chosen.

In an embodiment a number of sensor elements are read at the same time. The addressing of the bit cells is done by means of an array of crossing lines. The read-out method depends on the type of sensor. In the case of pseudo-spin valves a number of cells (N) can be connected in series in the word line, because the resistance of these completely metallic cells is relatively low. This provides the interesting advantage that only one switching element (usually a transistor) is needed per N cells. The associated disadvantage is that the relative resistance change is divided by N. The read-out is done by measuring the resistance of a word line (with the series of cells), while subsequently a small positive plus negative current pulse is applied to the desired bit line. The accompanying magnetic field pulses are between the switching fields of the two ferromagnetic layers; thus the layer with the higher switching field (the sensing layer) will remain unchanged, while the magnetization of the other layer will be set in a defined direction and then be reversed. From the sign of the resulting resistance change in the word line it can be seen whether a ‘0’ or a ‘1’ is stored in the cell at the crossing point the word and the bit line. In an embodiment spin valves with a fixed magnetization direction are used and the data is detected in the other, free magnetic layer. In this case the absolute resistance of the cell is measured. In an embodiment the resistance is measured differentially with respect to a reference cell. This cell is selected by means of a switching element (usually a transistor), which implies that in this case one transistor is required per cell. Besides sensors with one transistor per cell, alternatively sensors without transistors within the cell are considered. The zero-transistor per cell sensor elements in cross-point geometry provide a higher density, but have a somewhat longer read time.

The memory device according to the invention is in particular suitable for the following applications. A first application is a portable device that needs exchangeable memory, e.g. a laptop computer or portable music player. The storage device has low power consumption, and instant access to the data. The device can also be used as a storage medium for content distribution. A further application is a smartcard. Also the device can be applied as secure memory that cannot be rewritten after the production. In an embodiment the device also has normal RAM memory in addition to the new memory cells. The new memory array part of the memory device is applied as memory that contains an operating system, program code, etc.

A further application is a memory that is very well copyright-protected. The protection benefits from the fact that if no recordable/rewritable version of the information storage device exists, a consumer reasonably cannot copy the read-only information from the sensor surface. For example, this type of memory is suitable for game distribution. In contrast to existing solutions it has, for example, the following properties: easily replicable, copy-protected, instant-on, fast access time, robust, no moving parts, low power consumption.

1. Method for storing information in a storage device (100, 200, 300), the storage device comprising a two-dimensional array of electromagnetic sensor elements (101) that are sensitive at a sensor surface (106) to electromagnetic material (104, 110, 112, 114, 202) within a near field working distance (105), the method for storing information comprising a step of:
depositing the electromagnetic material (104, 110, 112, 114, 202) in a pattern on the sensor surface (106), the pattern representing the information.

2. Method for storing information in a storage device (100, 200, 300) as claimed in claim 1, wherein the method further comprises a step of
aligning the pattern of electromagnetic material (104, 110, 112, 114, 202) to correspond to the array of electromagnetic sensor elements (101).

3. Method for storing information in a storage device (100, 200, 300) as claimed in claim 1, wherein the method comprises a printing step for depositing the electromagnetic material (104, 110, 112, 114, 202).

4. Method for storing information in a storage device (100, 200, 300) as claimed in claim 1, wherein the method comprises a stamping step for depositing the electromagnetic material (104, 110, 112, 114, 202), in particular a finger.

5. Method for storing information in a storage device (200) as claimed in claim 1, the storage device (200) having a cover layer (201) providing the sensor surface (106), wherein the step of depositing electromagnetic material (202) in a pattern comprises:
depositing a layer of electro-magnetic material (202) on the sensor surface (106), and comprises
creating a pattern of depressed portions (205) into the cover layer (201) whereby the sensor surface (106) in the depressed portions (205) is within the near field working distance (105) and the sensor surface (106) outside the depressed portions (205) is outside the near field working distance (105).

6. Method for storing information in a storage device (300) as claimed in claim 1 the storage device (300) having a cover layer (201) providing the sensor surface (106), wherein the method for storing information comprises a step of
embedding the electromagnetic material (104) into the cover layer.

7. Method for storing information in a storage device (100, 300) as claimed in claim 1, wherein the step of depositing electromagnetic material in a pattern comprises:
depositing a pattern comprising at least two types of electromagnetic material (104, 110), the types of electromagnetic material (104, 110) representing different values to the sensor elements (102, 103).

8. A storage device comprising a two-dimensional array of electromagnetic sensor elements (101) that are sensitive at a sensor surface (106) to electromagnetic material (104, 110, 112, 114, 202) within a near field working distance (105), wherein the sensor surface (106, 107) is arranged for depositing the electromagnetic material (104, 110, 112, 114, 202).

9. A storage device (100, 200, 300) as claimed in claim 8, wherein the sensor elements (102, 103) are arranged for sensing a value in a range of values depending on an amount of electromagnetic material (104, 112) within the near field working distance (105).

10. A storage device (100, 200, 300) as claimed in claim 8, wherein the sensor elements (102, 103) are arranged for detecting the presence of the electromagnetic material (104, 110, 112, 114, 202) in at least one of the following ways:
generating a magnetic field and detecting the magnetic field as influenced by the presence of absence of the electromagnetic material via a soft magnetic property; or
generating an electrical field and detecting the electrical field as influenced by the presence or absence of the electromagnetic material via a capacitive coupling; or
generating a fluctuating magnetic field and detecting the magnetic field as influenced by the presence of absence of the electromagnetic material via eddy currents.

11. A storage device (100, 200, 300) as claimed in claim 8, wherein electro-magnetic material (104, 110, 112, 114, 202) is deposited on the sensor surface (106) in a pattern, the pattern representing the information.

12. Method for manufacturing a storage device (100, 200, 300) as claimed in claim 8, comprising a step of
manufacturing a two-dimensional array of electromagnetic sensor elements (101) that are sensitive at a sensing surface (106) to electromagnetic material (104, 110, 112, 114, 202) within a near field working distance (105), and further comprising a step of
preparing the sensor surface (106, 107) for depositing electromagnetic material (104, 110, 112, 114, 202).

13. Method for manufacturing a storage device (100, 200, 300) as claimed in claim 12, wherein the method further comprises a step of
applying a cover layer (201) for providing the sensing-surface (106).

14. Printing fluid for use in the method for storing information in a storage device (100, 200, 300) as claimed in claim 1,
the printing fluid comprising the electromagnetic material (104, 110, 112, 114, 202) for depositing the pattern on the sensor surface (106).
